(19) United States
(12) Patent Application Publication
(10) Pub. No.: US 2025/0024669 A1
(43) Pub. Date: Jan. 16, 2025

(54) Programmable Read-Only Memory Cell

(71) Applicant: X-FAB Global Services GmbH, Erfurt (DE)

(72) Inventors: Rumen Rachinski, Sofia (BG); Aleksandar Radev, Sofia (BG)

(21) Appl. No.: 18/770,212

(22) Filed: Jul. 11, 2024

(30) Foreign Application Priority Data
Jul. 12, 2023 (GB) 2310721.2

(51) Int. Cl. H10B 20/25; G11C 17/16

(52) U.S. Cl. CPC H10B 20/25; G11C 17/165

(57) ABSTRACT

A one-time programmable memory cell having a transistor. The transistor includes a drain, a source, and a channel between the drain and the source. The transistor is connected to a data storage element and to a memory cell selection element. The channel of the transistor includes a first and a second channel portion. A dopant concentration in the first channel portion is higher than in the second channel portion.

### CROSS-REFERENCE TO RELATED APPLICATIONS

This application claims priority to United Kingdom Patent Application No. GB2310721.2, titled “A programmable read-only memory cell,” having a filing date of Jul. 12, 2023, which is incorporated herein by reference in its entirety and for all purposes.

### TECHNICAL FIELD

The present disclosure relates to memory cells, and more particularly to one-time programmable memory cells.

### BACKGROUND

A non-volatile memory (NVM) is a type of memory that does not require a continuous power supply to retain stored information. A particular type of NVMs are one-time programmable (OTP) memories which contain memory elements that can only be programmed once, and can no longer be modified after programming. OTP memories are used in a wide range of electronics products, for example in consumer products or safety critical systems.

An example of a known single OTP memory cell is illustrated in FIG. 1. The cell includes a transistor 100 and (as the memory element) a gate oxide capacitor 102. The OTP memory cell shown in FIG. 1 is an anti-fuse-type OTP memory cell, i.e. the memory element has a low conductivity before programming and high conductivity after programming. The transistor 100 allows the selection of a particular the memory cell (a memory device has typically a large number of memory cells) for programming or reading.

To program the memory cell of FIG. 1, a programming voltage is applied on a data line connected to the upper plate of the capacitor 102. At the same time a select voltage is applied to the gate of the transistor 100 to switch the transistor 100 “on” and a low voltage (e.g. 0V) is applied to the source of the transistor 100 (the pin PSUB of the transistor 100 is connected to ground). The programming voltage is chosen to be larger than the capacitor's breakdown voltage such that a gate oxide burning process happens, destroying the insulating properties of the gate oxide and establishing a conductive connection between the two plates of the capacitor 102, thereby programming the memory cell. Thus, the programming state of the memory cell can therefore be determined by measuring the current flowing through the capacitor 102.

It is frequently desirable (e.g. in battery powered systems) to implement memory cells with low-voltage transistors which can be operated with a low switching voltage. However, in the memory cell shown FIG. 1 the transistor 100 needs to be able to withstand the high voltage and current present during programming of the memory cell. For example, the transistor 100 may need to have a drain-source breakdown voltage higher than the (required) programming voltage. Consequently, the memory cell of FIG. 1 may not allow the use of low-voltage transistors.

### SUMMARY

A problem with conventional OTP memory cells is that these cells cannot be selected (e.g. for reading or programming operations) using low voltage signals. This means conventional OTP memory cells are not suitable, for example, for use in battery powered devices. To at least partly solve this problem, the present invention provides an improved memory cell, a method of operating the proposed memory cell, and an improved memory device such as set out in the accompanying claims.

In overview, the present invention aims to provide new and useful one-time programmable (OTP) memory cells and memory devices. In general, embodiments of the present invention may enable, for example, OTP memory cells that can be selected (for reading or programming operations) using a lower voltage compared to conventional OTP memory cells. Embodiments may achieve this by providing a transistor (between a data storage element and a memory cell selection element) which has a channel comprising (at least) two channel portions where a dopant concentration in one channel portion is higher than in the other channel portion. Such a transistor may protect the selection element from high voltages and high currents (and thereby potential breakdown damages) during programming of the memory cell. Thus, the selection element can be implemented, for example, by a low-voltage transistor which can be switched by applying a low voltage. Thus, embodiments may thereby be particularly suitable for battery powered devices. Further, embodiments may be realised with a small foot print and may be integrated to form high-density memory arrays. Embodiments of the present invention may be manufactured using conventional foundry processes.

### BRIEF DESCRIPTION OF THE DRAWINGS

Embodiments of the invention will now be described, by way of example only, with reference to the accompanying schematic drawings, in which:

FIG. 1 shows a known single OTP memory cell;

FIG. 2 shows a schematic of an OTP memory cell according to an embodiment;

FIG. 3 shows a cross section of a structure of the memory cell of FIG. 2;

FIG. 4 shows an equivalent circuit of the memory cell of FIG. 2 during programming of the memory cell;

FIG. 5 shows an experimentally obtained current measurement during programming of the memory cell of FIG. 2;

FIG. 6 shows an equivalent circuit of the programmed memory cell of FIG. 2;

FIG. 7 shows a cross section of a portion of the programmed memory cell of FIG. 2 when the memory cell is unselected and a programming voltage is applied;

FIG. 8 shows a schematic of an arrangement of four memory cells, and

FIG. 9 shows a layout of the arrangement of FIG. 8.

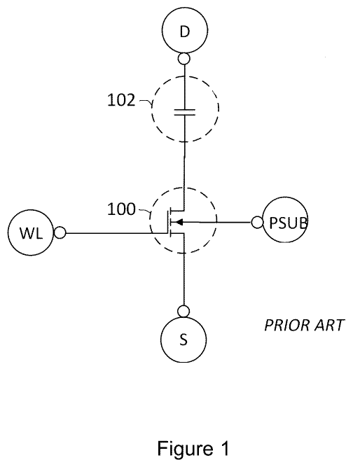

To avoid unnecessary repetition, like reference numerals will be used to denote like features in the figures.

### DETAILED DESCRIPTION

According to a first embodiment there is provided a one-time programmable memory cell. The one-time programmable memory cell comprises a transistor comprising a drain, a source and a channel between the drain and the source. The transistor is connected to a data storage element and to a memory cell selection element (e.g. a further transistor). The channel of the transistor comprises a first and a second channel portion (e.g. the two channels may be in direct contact with each other). A dopant concentration in the first channel portion may be higher than in the second channel portion.

Providing a transistor with two differently doped channel portions makes it possible, for example, to use a low-voltage device to implement the memory cell selection element. This is because the transistor can be operated to protect the memory cell selection element from potential damage during programming operations (i.e. operations that typically include high voltages and high currents).

The drain of the transistor may be connected to the data storage element and the source of the transistor may be connected to the memory cell selection element. The second channel portion may be adjacent to (e.g. in direct contact with) the drain of the transistor. In this way, a breakdown voltage between the drain and the gate of the transistor may be increased compared to a transistor that is provided, for example, with a lightly-doped drain region between the drain and channel of the transistor.

The transistor may further comprise a gate, and the source. The gate and the drain may be arranged next to each other in a lengthwise direction of the transistor. The first and second channel portions may extend along the lengthwise direction of the transistor respectively for a first and a second length. In particular, the first length may be equal or greater than a third of the second length. Additionally or alternatively, the first length may be equal or less than three times the second length. For example, the first length may be 50% greater than the second length.

The one-time programmable memory cell may further comprise a lightly doped source region extending between source and gate of the transistor. The drain and source may comprise respective n-doped regions, and the first channel portion may comprise a p-doped region. In some implementations, the one-time programmable memory cell may not comprise a lightly doped drain region extending between drain and gate of the transistor.

The transistor may be formed on a substrate having a substrate dopant polarity and a substrate dopant concentration. The second channel portion may have a dopant polarity and a dopant concentration which is substantially equal to the substrate dopant polarity and the substrate dopant concentration. This means that the second channel portion may be considered to be a “native” channel portion (e.g. forming this channel may not require an additional doping step).

The data storage element may be configured to be programmable by applying a programming voltage. The programming voltage may be higher than an operating voltage of the further transistor, and, when applied to the further transistor, the programming voltage would damage the further transistor. In this way, it is possible to use high programming voltages without increasing the risk of a breakdown of the further transistor.

In some implementations, the data storage element may be a capacitor formed on the substrate (i.e. the same substrate on which the transistor is formed on). The capacitor may comprise a source provided in the substrate, a gate oxide layer formed on the substrate, and an upper plate (for connection to a data pin) provided on top of the gate oxide layer. In some implementations, the one-time programmable memory cell may not comprise a lightly doped source region extending between the source of the capacitor and gate oxide layer of the capacitor.

According to another embodiment there is provided a method of programming or reading the memory cell according to the first embodiment. The method comprises applying a selection voltage to the memory cell selection element, applying a blocking voltage to the gate of the transistor, and applying a programming or a reading voltage to the data storage element to program or read the selected memory cell, wherein the blocking voltage is larger than the selection voltage and lower than the programming voltage. By providing a blocking voltage that is larger than the selection voltage and lower than the programming voltage, the voltage at the memory cell selection element received from transistor can be sufficiently low such that the risk damaging the memory cell selection element is low.

According to a further embodiment there is provided a memory device which comprises the memory cell according to the first embodiment.

According to another embodiment there is provided a memory device which comprises a first, second, third and fourth memory cell according to the first embodiment. The memory cell selection element of each memory cell comprises a respective further transistor comprising a gate. The memory device comprises further a shared data line for applying a programming or reading voltage. The shared data line is connected to the data storage element of each memory cell. The memory device comprises further a blocking line for applying a blocking voltage. The blocking line is connected to the gate of the transistor of each memory cell. The memory device comprises further a first and second selection line. The first selection line is connected to the source of the further transistor of the first memory cell and to the source of the further transistor of the third memory cell. The second selection line is connected to the source of the further transistor of the second memory cell and to the source of the further transistor of the fourth memory cell. The memory device comprises further a first and second word line. The first word line is connected to the gate of the further transistor of the first memory cell and to the gate of the further transistor of the second memory cell. The second word line connected to the gate of the further transistor of the third memory cell and to the gate of the further transistor of the fourth memory cell. The device is arranged such at least one of the four memory cells are selectable for programming or reading by applying a voltage to at least one of the selection and word lines.

The proposed memory device may provide the advantage that the number of contacts required for accessing the four memory cells for reading or programming is reduced when compared to an arrangement in which the four memory cells need to be individually accessed. The proposed memory device may further be realised in a compact manner, and may be formed using conventional low-voltage CMOS technology without additional technology steps or additional photolithography (e.g. additional masks). This means that the proposed memory device is suitable for use in high-volume, low-cost OTP memories.

In broad terms, an anti-fuse-type, one-time programmable (OTP) memory cell is proposed that can be formed in (and on) a semiconductor substrate with standard CMOS manufacturing processes. The memory cell comprises a data storage element, a transistor, and a memory cell selection element (connected in series). Programming the memory cell comprises applying a relatively high voltage (hereafter “programming voltage”) to the data storage element to cause an irreversible change of the conductivity of the storage element. A purpose of the transistor is to protect the memory cell selection element from the programming voltage such that the memory cell selection element can be implemented by an element that can be switched with a low-voltage, e.g. a low-voltage transistor.

Throughout this disclosure, any dimensions or voltage values refer to embodiments of the proposed memory cell when formed using conventional 0.11 μm MOS (Metal Oxide Semiconductor) processes. It is understood that such values are only examples and may vary when the proposed memory cell is formed using different process. For example, a person of ordinary skill in the art would understand that, when using 0.18 μm MOS processes, the respective dimensions and voltage values may be correspondingly greater.

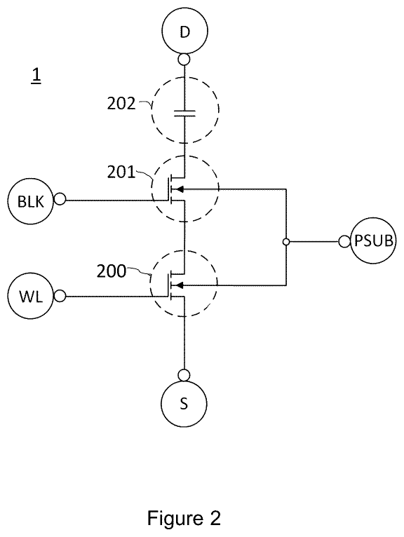

FIG. 2 shows a schematic of a one-time programmable (OTP) memory cell 1 according to an embodiment. The memory cell 1 comprises a memory capacitor 202 (as data storage element), a first transistor 200 and a second transistor 201. The first and second transistors 200, 201 comprise respective source, drain, gate and substrate contacts.

In general, in the embodiment of FIG. 2, the first and second transistors 200, 201 are low voltage n-channel transistors connected in series. The first transistor 200 is configured to enable the selection of the memory cell 1 for a reading or programming operation. The second transistor 201 is configured to perform a high potential lockout function during programming operations. Because the first and second transistors 200, 201 are low voltage transistors, the memory cell 1 can be selected for a reading or programming operation by applying a low voltage. For example, the memory cell 1, when formed using 0.11 μm MOS processes, may be selected for a reading operation by applying a voltage of 1.2V (to the gate contacts of the first and second transistors 200, 201, as described in detail below).

As mentioned above, the first transistor 200 is configured to allow selecting the memory cell for reading and programming operations. The gate of the first transistor 200 is connected to the select pin WL. The source of the first transistor 200 is connected to the pin S. The substrate of the first transistor 200 is connected to ground via a pin PSUB. The drain of the first transistor 200 is connected to the source of the second transistor 201.

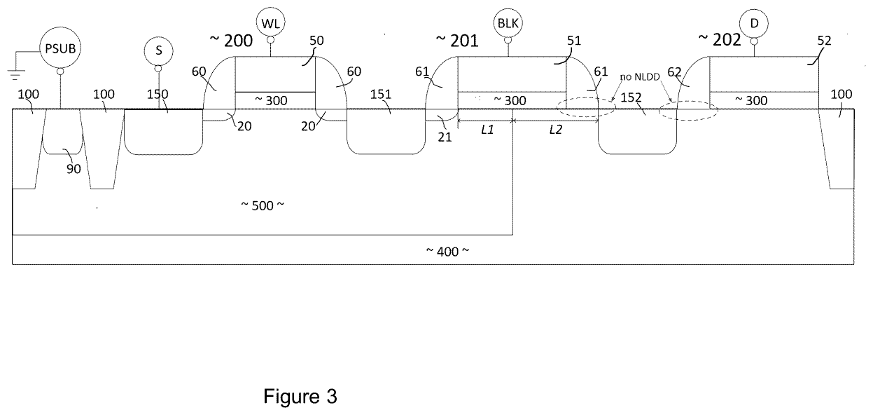

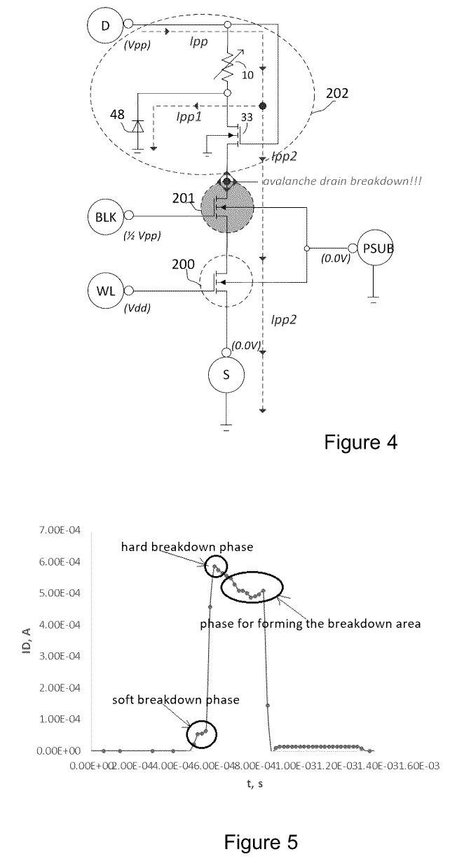

The second transistor 201 is configured to protect the first transistor 200 from damage during programming operations. To this end (and as further described below with reference to FIGS. 3 and 4), the second transistor 201 comprises a “split-channel”, i.e. its channel area comprises (at least) two parts which have different dopant concentrations. The gate of the second transistor 201 (hereafter “split-channel transistor 201”) is connected to a pin BLK. The substrate of the second transistor 201 is connected to ground via a pin PSUB. The drain of the second transistor 201 is connected to a bottom plate of the capacitor 202. An upper plate of the capacitor 202 is connected to a data pin D. The capacitor 202 may be a n-channel, low-voltage, native type capacitor with a thin gate oxide thickness. In this case, programming of the cell 1 is accomplished by breaking down the oxide of the capacitor 202 (as described in detail below with reference to FIGS. 4 and 5).

Referring now to FIG. 3, an example semiconductor structure implementing the memory cell 1 is described. The semiconductor structure comprises a semiconductor substrate 400. The substrate may have a low impurity concentration. The semiconductor structure comprises a p-type well 500 (i.e. a region in the substrate formed by ion implantation and in which low-voltage devices can be implemented). The semiconductor structure further comprises shallow-trench isolation (STI) regions 100 (i.e. trenches in the surface of the substrate filled with a STI material such as silicon oxide) around the transistors 200, 201 and the capacitor 202 (e.g. to provide isolation between individual memory cells when multiple cells are provided on the same substrate).

The memory capacitor 202 is provided on the substrate area 400 with a thin gate oxide 300. The thin gate oxide 300 may have a thickness approximately 2.9 nm when formed using a 0.11 μm MOS process. The top plate 52 of the capacitor 202 is connected to the data pin D of the memory cell 1. The top plate 52 may be formed of poly-Si. The source of the capacitor 202 is provided by a n-type active area 152 in the substrate area 400. A (thick) oxide spacer 62 provides isolation between the source region 152 and the top plate 52.

In contrast to conventional thin gate oxide capacitors, the capacitor source region 152 may be formed without a NLDD (n-type lightly doped drain/source) implantation area. In other words, the surface of the substrate 400 between the n-type active area 152 and the gate oxide 300 of the capacitor 202 may be native (i.e. of the same dopant polarity and the same dopant concentration as the substrate 400). As described below with reference to FIGS. 4 and 5, the absence of a NLDD implantation area in the capacitor source region 152 may increase the breakdown voltage between the capacitor plate 52 and the capacitor source region 152 once the memory cell 1 is programmed. The increased breakdown voltage may be a particular advantage of the memory cell 1. For example, the increased breakdown voltage may reduce the risk of a leakage current, when the memory cell is unselected and the high programming voltage is applied to the data pin D.

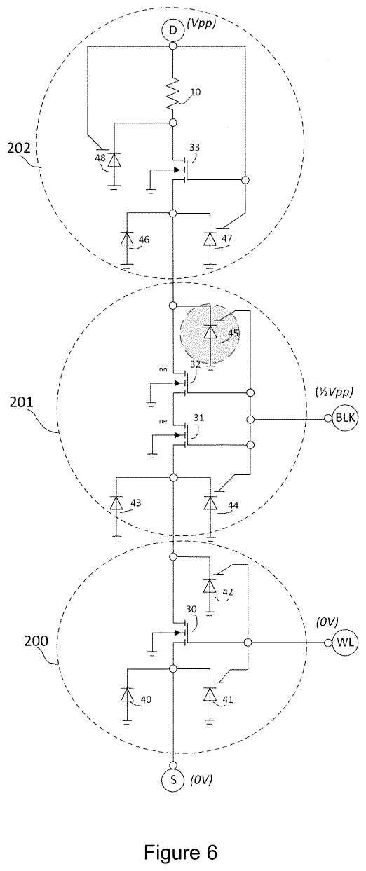

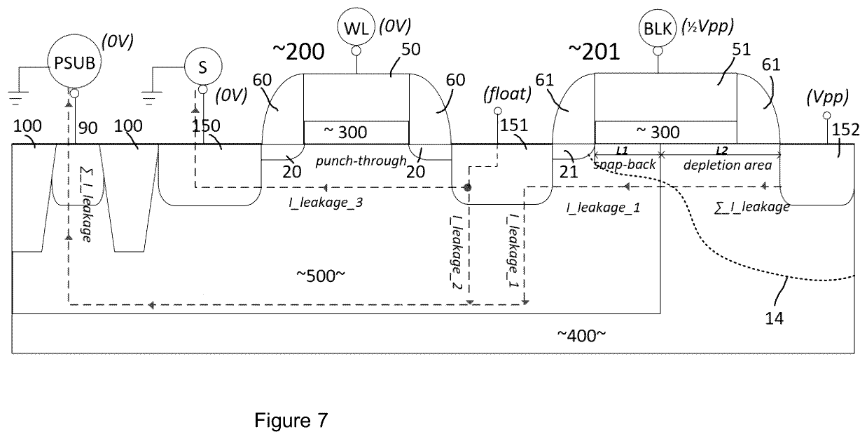

The split-channel transistor 201 comprises a gate 51 on top of a thin gate oxide layer 300. The gate 51 may be formed of poly-Si. The oxide layer 300 of the split-channel transistor 201 may have a thickness of about 2.9 nm when formed using a 0.11 μm MOS process. The gate 51 is connected to the blockage pin BLK of the memory cell 1. As described in detail below with reference to FIGS. 6 and 7, in the programming mode, a “blocking voltage” V_{BLK} is applied to the pin BLK. In general, the blocking voltage V_{BLK} is selected to be suitable (e.g., approximately equal to 50% of the programming voltage Vₚₚ) to protect the drain of the first (low-voltage) transistor 200 from the high voltage Vₚₚ applied to pin D. In other words, V_{BLK} may be selected so that (V_{BLK}−Vₜ) is smaller than the breakdown voltage of the drain of first transistor 200, where Vₜ is the threshold voltage of the split-channel transistor 201 (appropriately corrected to take into account the source/substrate voltage of the device).

The split-channel transistor 201 further comprises a first and a second channel portion L1 and L2. In general, the first and second channel portions have different doping concentrations. In an embodiment, the doping concentration in the first channel portion L1 may be at least 20 times higher than the doping concentration in the second channel portion L2. For example, when formed using a 0.11 μm MOS process, the doping concentration in the channel portion L1 may be 5.8e+17 cm⁻³ and the doping concentration in the channel portion L2 may be 2e+16 cm⁻³. In the embodiment of FIG. 3, the first channel portion L1 is provided in the p-type well 500 and may thereby act as an “enhancement” portion (hereafter referred to as “enhancement channel portion L1”). As shown in FIG. 3, the enhancement channel portion L1 is provided at the source side of the transistor. The second portion L2 may be provided in substrate 400 (i.e. the second channel portion may be considered a “native” portion, and the second channel portion L2 is referred to as “native channel portion L2” hereafter). In other words, the native channel portion L2 may have the same dopant polarity and the same dopant concentration as the substrate 400. In other embodiments, the second channel portion may have a different doping concentration than the substrate 400.

The native channel portion L2 is provided at the drain side of the split-channel transistor 201. In general, providing a channel portion at the drain side which has a lower doping concentration than a channel portion at the source side may reduce the risk of an avalanche breakdown at the drain during programming of the memory cell 1.

Conduction through the enhancement and native channel portions L1, L2 may be controlled by the common gate 51. As shown in FIG. 3, the source 151, the enhancement channel portion L1, the native channel portion L2 and the drain 152 of transistor 201 may be arranged next to each other in a lengthwise direction of the transistor. The enhancement and the native channel portions L1, L2 may extend along the lengthwise direction of the transistor 201 respectively for a first and a second length. As described in detail further below, the first length (i.e. the length of the enhancement portion L1 in the lengthwise direction of the transistor 201) may be selected to be sufficiently large so as to prevent a “snap-back” effect in the channel of the transistor 201 when the programmed memory cell 1 is unselected while the programming voltage is applied to data pin D.

In general, to achieve the above mentioned effect, the lengths of the enhancement and native portions may be selected based on doping of the p-type well 500 and doping of the substrate 400. For example, in an embodiment with a lower doping concentration of the p-type well 500, the length of the enhancement portion L1 may be increased accordingly. In an embodiment with a lower doping concentration of the substrate 400, the length of the native portion L2 may be increased accordingly.

In an embodiment, the first length may be equal to or greater than a third of the second length. Additionally or alternatively, the first length may be equal or less than three times the second length. In some embodiments, the first length may be 50% greater than the second length.

As one example, in an embodiment where the memory device 1 is formed using a 0.11 μm MOS process and the doping concentrations of the p-type well 500 is 5.8e+17 cm⁻³ and the doping concentrations of the p-type substrate 400 is 2e+16 cm⁻³ the lengths of the enhancement and the native channel portion L1, L2 may be equal, e.g. 0.4 μm.

Further, the enhancement and native channel portions L1, L2 may be provided with a width (i.e. the extend of these channel portions in a direction perpendicular to the lengthwise direction of the split-channel transistor 201 and parallel to the surface of the substrate 400) such that the conductance of the split-channel transistor 201 does not significantly limit the programming current during programming of the memory cell 1.

The semiconductor structure of FIG. 3 further comprises an n-type active region 151 in the p-type well 500 forming the source of the split-channel transistor 201. At the source side of the split-channel transistor 201 a NLDD region 21 is provided. The lightly-doped region 21 may extend between the source (i.e. the n-type active region 151) and the gate oxide 300 of the split-channel transistor 201.

The n-type active region 152 in the substrate area 400 forms the drain of the split-channel transistor 201 (as well as the source of the capacitor, as described above). Isolation between the gate 51 and drain region 152 of the split-channel transistor 201 is provided by the thick oxide spacer 61. The drain region 152 of the split-channel transistor 201 may be formed without a NLDD implantation area. In other words, the surface of the substrate 400 between the n-type active area 152 and the gate oxide 300 of the split-channel transistor 201 may be native (i.e. of the same dopant polarity and the same dopant concentration as the substrate 400). Thus, in contrast to conventional MOS transistors, the split-channel transistor 201 of FIG. 3 has an asymmetric-LDD structure in that a LDD area is provided between gate 51 and source 151 but no LDD area is provided between gate 51 and drain 152.

Advantageously, the absence of a NLDD implantation area in the transistor drain region 152 may increase the breakdown voltage between the gate 51 and the transistor drain region 152 once the memory cell 1 is programmed. Further, providing the drain of the split-channel transistor 201 as a n-type region surrounded by the (high-resistivity) p-type substrate area 400 ensures good protection of the transistor from an avalanche breakdown in the drain of the split-channel 201 transistor during programming of the memory cell when a large programming current flows through the channel of the split-channel transistor 201.

The first transistor 200 may be a conventional enhancement n-channel low-voltage transistor. The first transistor 200 is formed in the p-type well 500 and comprises a gate 50 on top of a thin gate oxide layer 300. The gate 50 may be formed of poly-Si. The oxide layer 300 of the first transistor 200 may have a thickness of about 2.9 nm when formed using a 0.11 μm MOS process. The gate 50 is connected to the pin WL of the memory cell 1. The drain of the first transistor 200 is provided by the n-type active region 151 (which is also the source of the split-channel transistor 201, as described above). The source and drain regions of the first transistor 200 comprise conventional NLDD regions 20 and oxide spacers 60. The source 150 of the first transistor 200 is connected with the pin S of the memory cell 1. The semiconductor structure comprises further a p-type active region 90 in the p-type well 500 providing a contact to the substrate. The p-type active region 90 is connected to the PSUB pin of the memory cell 1.

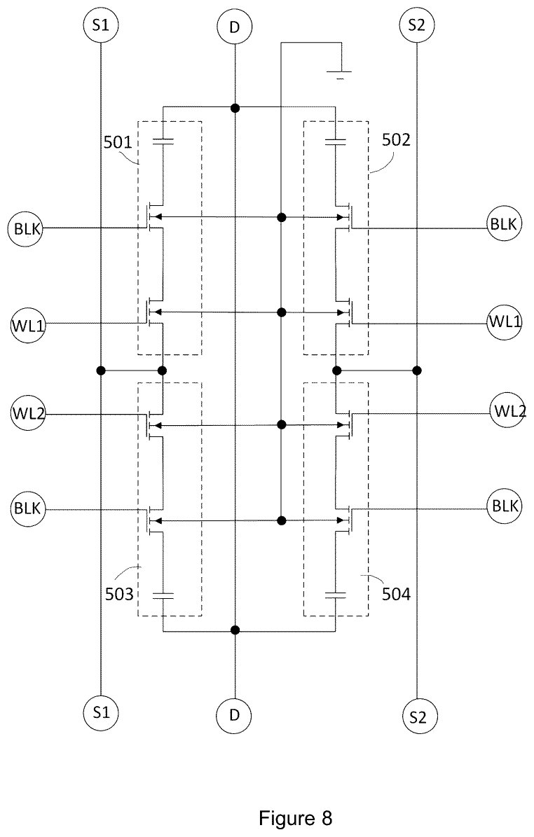

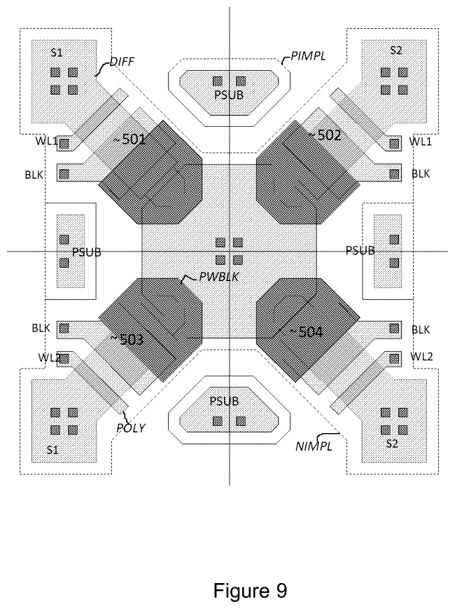

An operation of the memory cell 1 will now be described. The memory cell 1 may be part of a memory matrix which in turn may form together with associated peripheral circuits (e.g. for enabling the reading and programming of the cells) a OTP memory device. In this case, a data line connected to the data pin D may be shared with multiple memory cells of the memory device (an example arrangement of four memory cells is described below with reference to FIGS. 8 and 9). As described in detail further below, when the memory device is in a programming mode or a reading mode, a respective programming or reference voltage is applied to the data pin D. To allow operation in such a “shared data loop” configuration, the memory cell 1 may be configured to be programmed or read only when selected, and to not interfere with the programming or reading of other memory cells when not selected (as described below, this may be achieved by applying appropriate voltages to the first transistor 200 and the split-channel transistor 201).

In general, the memory cell 1 may be selected such that the bit value stored in the memory cell 1 can be read or that the memory cell 1 can be programmed. The memory cell 1 may be selected by switching the first transistor 200 “on”, i.e. by applying a “select” voltage V_{select} to the pin WL (connected to the gate of the first transistor 200), and a low voltage (typically 0V) to pins S and PSUB. The select voltage may be higher than a threshold voltage of the first transistor 200, for example, V_{select}=1.2 V when the memory cell 1 is formed using 0.11 μm MOS processes. In this case, the first transistor 200 is “on” because its gate-source voltage is positive and higher than its threshold voltage. In some embodiments, the select voltage V_{select} may correspond to a supply voltage at a memory device comprising the memory cell 1 operates.

To read or program the selected memory cell 1, the appropriate voltages may be applied to pins BLK and D. In particular, to read the stored bit value, a reference current (or reference voltage) is applied to the data pin D, and a low voltage (for example V_{select}, i.e. approximately 1.2 V when the memory cell 1 is formed using 0.11 μm MOS processes) is applied to the pin BLK (connected to the gate 51 of the split-channel transistor 201). In this case, the first transistor 200 and the split-channel transistor 201 are “on”, and the potential of the data pin D depends on the resistivity of the gate oxide 300 of the capacitor 202. When the memory cell 1 is unprogrammed, the gate oxide 300 of the capacitor 202 is intact, and the potential on the data pin D is high (this state may correspond to a logical “0” state of the memory cell 1). When the memory cell 1 is programmed, the gate oxide 300 of the capacitor 202 is damaged (i.e. shortened), and the potential on the data pin D is low (because both the first and the split-channel transistor are “on”). This state may correspond to a logical “1” state of the memory cell 1. Thus, the memory device can determine the stored bit value of the memory cell 1, for example, by determining the potential of the data pin D.

To program the selected memory cell 1, a (high) programming voltage Vₚₚ (for example, Vₚₚ=7.4 V when the memory cell 1 is formed using 0.11 μm MOS processes) is applied to the data pin D (connected to the upper plate 52 of the capacitor 202), and the blocking voltage V_{blk} is applied to pin BLK (connected to the gate 51 of the split-channel transistor 201). Generally, the blocking voltage may be higher than V_{select} (applied to pin WL) and may be lower than Vₚₚ (applied to the data pin D). In some examples, the blocking voltage V_{blk} may be approximately half of the programming voltage Vₚₚ, i.e. V_{blk}=Vₚₚ/2. In this case, the bottom plate of the capacitor 202 is at a low potential since both the first transistor 200 and the split-channel transistor are “on”. The programming voltage Vₚₚ is selected to be higher than a gate-oxide breakdown voltage of the capacitor 202. As a consequence, the gate oxide 300 of the capacitor 202 is damaged (i.e. shortened) during programming of the memory cell 1.

Some particular advantages of the memory cell 1 may be understood by considering in detail the breakdown of the capacitor 202 during programming of the memory cell 1 which is described in the following with reference to FIGS. 4 and 5. FIG. 4 shows an equivalent circuit of the memory cell 1 when the memory cell is programmed, and FIG. 5 shows experimentally obtained values of an electrical current flowing through the capacitor 202 (during breakdown of the capacitor 202). In general, it has been found that the breakdown of the capacitor 202 may be described as a process having three phases: a soft-breakdown phase, a hard-breakdown phase and a phase of forming a breakdown area.

The initial phase of the breakdown (i.e. the soft-breakdown phase) starts when a voltage difference between the memory capacitor plates becomes larger than the gate-oxide breakdown voltage (which happens, as mentioned above, when the programming voltage Vₚₚ is applied to the data pin D and the potential of the bottom plate of the memory capacitor 202 is low, because both the first and split-channel transistor 200, 201 are “on”). Then, a current Iₚₚ of some tens of microamperes starts to flow through the memory cell 1 (i.e. through the first and split-channel transistors 200, 202 to the pin S, as indicated in FIG. 4). At this point, there is substantially no current Iₚₚ₁ into the substrate 400. In this phase, the resistance 10 of the intact gate oxide of the memory capacitor 202 limits the current. The resistance 10 of the intact gate oxide may typically be on the order of tens of MΩ but this is only an example. It is understood that the resistance 10 of the intact gate oxide depends on the specific geometry of the capacitor 202 and the thickness of the gate oxide 300. Up to this stage, the capacitor has not undergone an irreversible transformation, i.e. if the voltage applied to pin D is lowered at this stage of the process, the oxide recovers to its original state. At his stage, the channel resistances of the first and the split-channel transistors 200, 201 are significantly lower than the resistance of the unbroken capacitor gate oxide.

During the soft-breakdown phase, the gate oxide 300 of the capacitor 202 a “self-heating” effect may occur. When the “self-heating” of the gate oxide 300 exceeds a (design specific) threshold, the “hard-breakdown” phase starts where the programming current Iₚₚ sharply rises to hundreds of microamperes (as shown in FIG. 5) and the structure of the gate oxide 300 starts to undergo irreversible changes (i.e. the gate oxide is getting irreversible damaged). Generally, the program current Iₚₚ may be determined by the (large) substrate current Iₚₚ₁, and the current that flows through the channels of the transistors of the memory cell Iₚₚ₂ (as indicated in FIG. 4). At this stage, the substrate current Iₚₚ₁ may cause the transfer of material from the top plate 52 of the memory capacitor 202 to the substrate 400. As a consequence, an effective p-n junction diode 48 and an effective “native” transistor 33 may be formed, whereby the drain of transistor 33 may be connected to diode 48 and the source may be connected to the n-type area 152 (as shown in FIG. 4). This newly formed configuration may be beneficial in that it enables robust isolation of the memory cell 1 during programming and read operations when the cell is in not selected which in turn enables the arrangement and operation of multiple memory cells in a highly integrated manner which is described in detail below with reference to FIGS. 8 and 9. The transistors 200 and 201 may be configured that, during the hard-breakdown phase, the conductivity of the channels of the transistors 200 and 201 is sufficiently high such that the Iₚₚ₂ portion of the programming current Iₚₚ is high enough to ensure the non-reversible breakdown of the gate oxide 300 of the memory capacitor 202.

In particular, as mentioned above, the channel width of the split-channel transistor 201 may be selected to be sufficiently large (e.g. in particular large enough to compensate any resistance associated with the low doping concentration of the native channel portion L2) such that the conductance of the split-channel transistor 201 during the hard-breakdown phase may be sufficiently high so as to not significantly limit the programming current Iₚₚ. A particular advantage of the memory cell 1 may be that by providing a native channel portion at the drain side of the split-channel transistor the risk of an avalanche breakdown (and thereby damage to the memory cell) caused by the large programming current is reduced compared to a conventional transistor device with a uniformly doped channel. This risk may be further reduced by providing the drain of the split-channel transistor 201 (i.e. the n-type active region 152) without a NLDD region.

Further, the first transistor 200 may be configured to provide a sufficiently high conductivity such that the large programming current Iₚₚ₂ during the hard-breakdown phase can flow through the first transistor 200 thereby ensuring the start of the oxide destruction (in embodiments where the memory cell 1 is formed using for the 0.11 μm MOS processes, Iₚₚ₂ may exceed 200 μA). As mentioned above, the memory cell is in a selected state, i.e. the first transistor 200 receives a low select voltage V_{select} at the gate, and a low voltage (e.g. 0 V) at the source. The voltage at the drain may be approximately equal to (V_{BLK}−Vₜ) where Vₜ is the threshold voltage of the split-channel transistor 201 (e.g. approximately 0.8V). Thus, in embodiments where the blocking voltage V_{BLK} is half of the programming voltage Vₚₚ, the voltage at the drain of the first transistor may be (½Vₚₚ−Vₜ). A particular advantage of the memory cell 1 may be that a channel length of the first transistor 200 can be shorter than in conventional OTP memory cells since the voltage at the drain is lower (for example, about 2.5V when where the memory cell 1 is formed using for the 0.11 μm MOS processes). This makes it possible to reduce the size of the memory cell 1 (i.e. to provide the memory cell 1 with a smaller footprint).

During the final phase of the capacitor breakdown, the resistance of the fractured gate oxide may decrease as a result of the destruction of the gate oxide 300. The part of the programming current Iₚₚ₂ which flows through the first and split-channel transistor 200, 201 may change and stabilize at a lower value which may be determined by the common resistance of destroyed capacitor gate oxide 10, the channel resistance of the split-channel transistor 201 and the channel resistance of the first transistor 200. Typically, the resistance of the fractured gate oxide 10 may be on the order of tens of kilo-ohms after the breakdown process has been completed.

As mentioned above, the memory cell 1 may be configured to respectively not undergo programming or affect the read out signal when the memory signal is unselected. For example, the memory cell 1 may be configured such that, when the memory cell 1 is unprogrammed and not selected, the capacitor 202 may not undergo the above described breakdown in programming mode (i.e. when the programming voltage Vₚₚ is applied to the data pin D, and the blocking voltage V_{BLK} is applied to pin BLK). For example, the memory cell 1 may be in an unselected state because the first transistor 200 is in an “off” state (e.g. when a low voltage (e.g. 0V) is applied to the pins WL, S and PSUB). Thus, in this case the source of the capacitor 202 source may be floating. As a consequence, no inversion layer may be formed under the capacitor plate 52 (only a depletion area in the substrate 400). The capacitance of the depletion area C_{dpl} may be low in comparison with gate capacitance Cₒₓ. The formed capacitor divider may define the surface potential V₁ under the capacitor plate 52 nearly to potential of the upper poly plate (V₁=Vₚₚ*Cₒₓ/(Cₒₓ+C_{dpl}). That's why the electric field over the gate oxide 300 of the capacitor 202 is very low (Vₚₚ−Vₜ≈0V) and the gate oxide 300 may not undergo the above described breakdown process.

In general, the memory cell 1 may be further configured such that in programming mode (i.e. when the programming voltage Vpp is applied to the data pin D, and the blocking voltage VBLK is applied to pin BLK) and when the memory cell 1 is programmed and not selected, no substantial leakage current flows through the memory cell 1, and no breakdown occurs. As mentioned above, the memory cell 1 may be in an unselected state because the first transistor 200 is in an “off” state (e.g. when a low voltage (e.g. 0V) is applied to the pins WL, S and PSUB). Because the memory cell 1 is programmed in this example, the potential of the drain 152 of the split-channel transistor 201 may be close to the programming voltage (because of the broken gate oxide of the memory capacitor 202). In this case, the source 151 of the split-channel transistor 201 is floating.

With reference to FIGS. 6 and 7, a detailed description of relevant breakdown voltages of the memory cell 1 is now provided to illustrate that the breakdown voltage of an unselected but programmed memory cell 1 is greater than the programming voltage Vₚₚ (and that thus the memory cell 1 can be operated in an arrangement where multiple memory cells share a data line connected to the pin D without a significant risk of breakdown). FIG. 6 shows a corresponding equivalent circuit and FIG. 7 shows a cross section of a portion of the (programmed and not selected) memory cell 1. Referring to FIG. 6, after programming, the equivalent circuit of the memory capacitor 202 may comprise the ohmic resistance 10 of the broken oxide structure of the memory capacitor 202, the p/n junction diode 48 (formed during in the breakdown process of the memory capacitor 202 by material transfer from the plate 52 to the substrate 400), the above described transistor 33, and diodes 46 and 47. A bulk breakdown voltage of the diode 48 may be very high since it is formed in the (high resistivity) p-type substrate 400. The diode 48 may be effectively a gated diode, i.e. its breakdown voltage depends on the potential of the gate 52. For example, the breakdown voltage of the diode 48 may increase for increasing potential of the plate 52. Thus, when the programming voltage Vₚₚ is applied to pin D, the breakdown voltage of the diode 48 may be sufficiently high (i.e. higher than the programming voltage Vₚₚ, e.g. the breakdown voltage of the diode 48 may be about 13.0V when the memory device 1 is formed using 0.11 μm MOS processes).

The transistor 33 may be in a diode connection (i.e. its drain and gate may be connected through the resistance 10). The drain of transistor 33 may be formed in the aforementioned substrate p/n junction 48, the gate of transistor 33 may be the plate 52 and the source of transistor 33 may be the source region 152 of the memory capacitor 202. The diode 47 may be a p/n junction between the source area 152 of the memory capacitor 202 and the p-type substrate 400. Like the diode 48, the diode 47 may be gated. The diodes 47 and 48 may have the plate 52 as common gate. A breakdown voltage of the diode 47 may be similar to the breakdown of the diode 48. The diode 46 may be a bulk p/n junction between the source area 152 of the memory capacitor 202 and p-type substrate 400. The diode 46 may be of a conventional type having a breakdown voltage (defined by the manufacturing process) which is in practice is typically very high (e.g. about 25V when the memory device 1 is formed using 0.11 μm MOS processes). As mentioned above, the breakdown voltage between the plate 52 and the source 152 of the memory capacitor 202 is very high, when no NLDD implantation area in the source region of the capacitor is provided. Thus, in general, the lowest breakdown voltages of the equivalent circuit of the capacitor 202 after programming may be determined by the diodes 47 and 48 and may be sufficiently high (i.e. sufficiently higher than the Vₚₚ when Vₚₚ is applied to pin D).

Referring to FIGS. 6 and 7, the breakdown voltage of the drain of the split-channel transistor 201 is now described (when the memory cell 1 is programmed and not selected). In the equivalent circuit of FIG. 6, the representation of the split-channel transistor 201 comprises two conventional n-channel transistors 32 and 31. Transistor 32 represents the native channel portion of the split-channel transistor 201 and may be considered to be a conventional low voltage native type transistor. The drain of the transistor 32 may be connected to the source 152 of the storage capacitor 202. The gate of the transistor 32 may be connected to the blocking pin BLK. The source of the transistor 32 may be connected to the drain of transistor 31. Transistor 31 represents the enhancement channel portion of the split-channel transistor 201 and may be considered to be a conventional low voltage enhancement type transistor. The drain of the transistor 31 may be connected to the source of transistor 32. The gate of the transistor 31 may be connected to the pin BLK. The source of the transistor 31 source may be connected to the drain of the first transistor 200.

The drain breakdown voltage of the split-channel transistor 201 may be in part determined by the breakdown voltage between the gate and drain of the transistor. As illustrated in FIG. 7, the native channel portion L2 (represented by the native transistor 32 in the equivalent circuit of FIG. 6) is located at the drain side of the split-channel transistor 201. As mentioned above, when no NLDD at the drain of the transistor 201 is provided, the breakdown voltage between the gate and the drain of the split-channel transistor 201 is sufficiently high (i.e. not a limiting factor for determining the breakdown voltage at the drain).

The drain breakdown voltage of the split-channel transistor 201 may be further determined by the (effective) gated diode 45, shown in FIG. 6. The diode 45 may be formed by a p/n junction between the drain area 152 of the split-channel transistor 201 and the p-type substrate 400). The diode 45 may be a gated diode (because the gate oxide 300 of the split-channel transistor 201 is very thin), similar to the gated diode 47 described above. As a consequence, the breakdown voltage of the diode 45 is very high when the blocking voltage V_{BLK} applied to gate of split-channel transistor 201 is sufficiently high (for example, in embodiments where the memory cell 1 is formed using 0.11 μm MOS processes, the breakdown voltage of diode 45 may be about 9.0V when V_{BLK} is equal to ½Vₚₚ).

In FIG. 6, the gated diode 44 represents the p/n junction between the source 151 and the p-type well 500. The breakdown voltage of diode 44 breakdown voltage may depend on the blocking voltage V_{BLK} applied to gate of split-channel transistor 201. For example, when the blocking voltage V_{BLK} is about ½ Vₚₚ, the breakdown voltage of the diode 44 may be higher than the breakdown value of conventional diodes of this type (for example the breakdown voltage may be about 7.0 V instead of about 5.5 V conventional diodes, when the memory cell is formed using 0.11 μm MOS processes). The breakdown voltage of the diode 44 may be less than the breakdown voltage of the diode 45 because the p/n junction is realized in the p-type well 500, which may have a higher impurity concentration compared to the high-resistivity p-type substrate 400 (in an embodiment where the memory device 1 is formed using a 0.11 μm MOS process, the doping concentrations of the p-type well 500 may be 5.8e+17 cm⁻³ and the doping concentrations of the p-type substrate 400 may be 2e+16 cm⁻³). The diode 43 of FIG. 6 may be a bulk p/n junction between the n-type area 151 and the p-type well 500 with a breakdown voltage that may be lower than the breakdown voltage of the gated diode 44 (for example, about 5.5 V conventional diodes, when the memory cell is formed using 0.11 μm MOS processes).

As mentioned above, when the memory cell 1 is programmed and not selected, the drain of the first transistor 200 may not exceed a value of about (V_{BLK}−Vₜ). As a consequence, the drain of the first transistor 200 may be on a relatively low potential. This eliminates (or at least significantly reduces) the risk of a drain-gate breakdown of the conventional low-voltage n-channel first transistor 200.

The equivalent circuit of the first transistor 200 may comprise a diode 42 from which represents the p/n junction between the drain 151 and the p-type well 500, and which is similar to the diode 44 described above, i.e. the breakdown voltage of diode 42 may depend on the potential applied to the gate of the first transistor 200 (because of the very thin gate oxide 300). When the memory cell 1 is not selected, the gate potential of the first transistor 200 may be low (0V). In this case, the breakdown voltage of diode 42 may be equal to the breakdown voltage of the conventional diode 43 described above. The equivalent circuit of the first transistor 200 may further comprise a diode 41 which represents the source of the first transistor 200 and may also be a gated diode (similar to diode 42). As before, when the memory cell 1 is not selected, the gate potential of the first transistor 200 may be low (0V), and the breakdown voltage of diode 41 may be equal to the breakdown voltage of the conventional diode 43 described above. The equivalent circuit of the first transistor 200 may further comprise a diode 40 connected in parallel with diode 41 and presenting a bulk p/n junction between the n-type area 150 and the p-type well 500. The diode 40 may have a similar breakdown voltage as the diode 43 described above. Thus, from the above description with reference to FIGS. 6 and 7 it is apparent that the breakdown voltage of an unselected but programmed memory cell 1 may be determined by the breakdown voltage on the drain of the split-channel transistor 201, which is greater than the programming voltage Vₚₚ.

As mentioned above, in addition of having a sufficiently high breakdown voltage, the memory cell 1 is also configured to, when programmed but not selected, prevent any substantial leakage current in programming mode. This is now further described with reference to FIGS. 6 and 7. In general, no additional leakage current at the drain of the split-channel transistor 201 occurs, since, as described above, the breakdown voltage of the gated diode 45 (that presents the drain of the split-channel transistor 201) is higher than the programming voltage Vₚₚ when the blocking voltage V_{BLK} applied to pin BLK is about ½Vₚₚ. As a consequence, no leakage current may flow through the diode 45 to the substrate 400. As indicated in FIG. 7, when a potential close to Vₚₚ is applied to the drain 152 of the split-channel transistor 201, the depletion area 14 of the p/n junction at the drain 152 may extend through the native channel portion L2 and may touch the enhancement channel portion L1 of the split-channel transistor 201. The length of the enhancement portion L1 may be selected to prevent a “snap-back” phenomenon (see FIG. 7). In other words, the length of the enhancement channel portion L1 may be sufficiently long to prevent the depletion area 14 from extending to the (floating) source 151 of the split-channel transistor 201. This is because if the enhancement portion L1 is too short the (close to Vₚₚ) potential of the drain of the split-channel transistor 201 can reach the source 151. This potential is higher than the breakdown voltage of the gated diode 44 (described above), and as a consequence a leakage current (indicated as “I_leakage_1” in FIG. 7) may flow from the drain 152 of the split-channel transistor 201, through the depletion region 14 of the channel portions L1, L2, the source junction 151 of the split-channel transistor 201, and the substrate 500 to the substrate contact 90. In addition, to the aforementioned leakage current, a “snap-back” may also result in an additional leakage current (“I_leakage_2” in FIG. 7) because the gated diode 42 may also be in a breakdown condition. Thus, the additional leakage current may flow through the depletion region 14 of the channel portions L1, L2, the diode 42, and the substrate 500 to substrate contact 90. Further, a “snap-back” may also cause a “punch-through” effect in the channel region of the first transistor 200 which can cause a third leakage current (“I_leakage_3” in FIG. 7) flowing from the drain 151 of the first transistor 200 drain through the channel to the source 150 (as illustrated in FIG. 7). The aforementioned “snap-back” phenomenon (when the cell is programmed and not selected, and the memory device is in the programming mode) and additional leakage currents at the common data pin D (in the programming mode) are therefore prevented by appropriately selecting the length L1 of the enhancement portion of the split-channel transistor 201. This allows the memory cell 1 to be suitable for use in high-volume OTP memories.

In general, the memory cell 1 may be further configured such that in reading mode (i.e. when a reference current is applied to the data pin D, and a low voltage is applied to pin BLK to switch “on” the split-channel transistor 201) and when the memory cell 1 not selected (i.e. the first transistor 200 is “off”) no substantial leakage current flows through the memory cell 1. When the memory cell is not programmed, there is no current path because the memory capacitor 202 is not broken and the first transistor 200 is “off”. Since there is no leakage current, the potential of the data pin D is high. When the memory cell is programmed, the source of the split-channel transistor 201 is floating because the first transistor 200 is “off”. There is no current path in the memory cell 1 for the reference current, since the drain of the split-channel transistor 201 is at a potential which is too low (e.g., 1.2V) to cause leakages from the drain of the split-channel transistor 201. This means that the potential at the data pin D remains high.

The memory cell 1 (described above with reference to FIGS. 2 to 7) may enable memory devices with a high memory density (i.e. a large number of memory cell implemented in a small area). With reference to FIGS. 8 and 9, an example arrangement is described in which a 4-bit cluster (i.e. four instances of memory cell 1) are implemented in a compact manner. FIG. 8 shows a schematic of the 4-bit cluster, and FIG. 9 shows a corresponding layout. In general, the 4-bit cluster may be formed using conventional low-voltage CMOS technology without additional technology steps or additional photolithography (e.g. additional masks). This means that the 4-bit cluster can be manufactured at low cost making it suitable for use in high-volume, low-cost OTP memories. Moreover, as shown in FIG. 8, the 4-bit cluster can be implemented in a highly integrated manner. For example, when formed using 0.11 μm MOS processes, the 4-bit cluster may be implemented in an area of approximately 6.7 μm² per bit (i.e. per memory cell).

The 4-bit cluster shown in FIGS. 8 and 9 comprises first to fourth memory cells 501-504. Each of the memory cells 501-504 may be implemented as an instance of the memory cell 1 described above. As can be seen from FIG. 8, the memory cells 501-504 share a common data pin (i.e. the common data pin D is connected to the memory capacitors of the memory cells 501-504). Further, the memory cells 501-504 share a common pin BLK (connected to the gates of the split-channel resistors of the memory cells 501-504).

The 4-bit cluster may further comprise select pins WL1, WL2, S1 and S2. The select pin WL1 may be connected to the select pins WL of the memory cells 501 and 502, and the select pin WL2 may be connected to the select pins WL of the memory cells 503 and 504. The select pin S1 may be connected to the pins S of the memory cells 501 and 503, and the select pin S2 may be connected to the pins S of the memory cells 502 and 504. The memory cells 501-504 may share a common pin PSUB which may be connected to ground. The 4-bit cluster allows the organization of a memory matrix with which high-density OTP memories can be realized (i.e. OTP memories with large ratios of storage capacity to required area). This is illustrated in FIG. 9 where a layout of the 4-bit cluster is shown. The layout of FIG. 9 can be manufactured using 0.11 μm MOS processes. The small memory area of the memory matrix is achieved by sharing the contacts to date pin D and select pin S between 4 adjacent cells.

In programming or read mode only one of the four memory cells 501-504 is selected. The selected memory cell can then be programmed or read as described above with reference to memory cell 1. Each memory cell 501-504 can be selected in programming or read mode by applying the appropriate voltages to pins WL1, WL2, S1 and S2. Table 1 shows example voltage levels that may be applied to pins WL1, WL2, S1 and S2 respectively to select the individual memory cells 501-504. For example, memory cell 501 can be selected when WL1=Vₛₑₗ, WL2=0V, S1=0 and S2=Vₛₑₗ; memory cell 502 can be selected when WL1=Vₛₑₗ, WL2=0V, S1=Vₛₑₗ and S2=0V, etc. As mentioned above, the select voltage V_{select} may be approximately 1.2 V when the memory cells are formed using 0.11 μm MOS processes.

TABLE 1

| | Memory | Memory | Memory | Memory |
|---|---|---|---|---|
| | cell 501 | cell 502 | cell 503 | cell 504 |
| WL1 | Vₛₑₗ | Vₛₑₗ | 0 V | 0 V |
| WL2 | 0 V | 0 V | Vₛₑₗ | Vₛₑₗ |
| S1 | 0 V | Vₛₑₗ | 0 V | Vₛₑₗ |
| S2 | Vₛₑₗ | 0 V | Vₛₑₗ | 0 V |

When one of the memory cells is selected, the other memory cells are not selected. As described above with reference to memory cell 1, the memory cells may be configured to not affect the programming or reference voltage when in an unselected state.

Whilst certain embodiments have been described, these embodiments have been presented by way of example only, and are not intended to limit the scope of the inventions. Indeed, the novel devices, and methods described herein may be embodied in a variety of other forms; furthermore, various omissions, substitutions and changes in the form of the devices, methods and products described herein may be made without departing from the spirit of the inventions. The accompanying claims and their equivalents are intended to cover such forms or modifications as would fall within the scope and spirit of the inventions.

1. A one-time programmable memory cell comprising:
a transistor comprising a drain, a source and a channel between the drain and the source, the transistor being connected to a data storage element and to a memory cell selection element, wherein the channel of the transistor comprises a first and a second channel portion, a dopant concentration in the first channel portion being higher than in the second channel portion.

2. The one-time programmable memory cell according to claim 1, wherein the drain of the transistor is connected to the data storage element and the source of the transistor is connected to the memory cell selection element, and wherein the second channel portion is immediately adjacent to the drain of the transistor.

3. The one-time programmable memory cell according to claim 1, wherein the transistor further comprises a gate, and the source, the gate and the drain are arranged next to each other in a lengthwise direction of the transistor, and wherein the first and second channel portions extend along the lengthwise direction of the transistor respectively for a first and a second length.

4. The one-time programmable memory cell according to claim 3, wherein the first length is equal or greater than a third of the second length.

5. The one-time programmable memory cell according to claim 3, wherein the first length is equal or less than three times the second length.

6. The one-time programmable memory cell according to claim 3, wherein the first length is 50% greater than the second length.

7. The one-time programmable memory cell according to claim 3, further comprising a lightly doped source region extending between source and gate of the transistor.

8. The one-time programmable memory cell according to claim 1, wherein said drain and source comprise respective n-doped regions, and the first channel portion comprises a p-doped region.

9. The one-time programmable memory cell according to claim 1, wherein the transistor is formed on a substrate having a substrate dopant polarity and a substrate dopant concentration, and wherein the second channel portion has a dopant polarity and a dopant concentration being substantially equal to the substrate dopant polarity and the substrate dopant concentration.

10. The one-time programmable memory cell according to claim 1, wherein the first channel portion is adjacent to the second channel portion.

11. The one-time programmable memory cell according to claim 1, wherein the memory cell selection element comprises a further transistor.

12. The one-time programmable memory cell according to claim 11, wherein an operating voltage of the further transistor is equal to or less than 1.2V.

13. The one-time programmable memory cell according to claim 11, wherein the data storage element is configured to be programmable by applying a programming voltage, the programming voltage being higher than an operating voltage of the further transistor, and wherein the programming voltage applied to the further transistor would damage the further transistor.

14. The one-time programmable memory cell according to claim 1, wherein the one-time programmable memory cell does not comprise a lightly doped drain region extending between drain and gate of the transistor.

15. The one-time programmable memory cell according to claim 1, wherein the data storage element is a capacitor formed on a substrate, the capacitor comprising:
a source provided in the substrate;
a gate oxide layer formed on the substrate; and
an upper plate, for connection to a data pin, provided on top of the gate oxide layer, wherein the one-time programmable memory cell does not comprise a lightly doped source region extending between the source of the capacitor and the gate oxide layer of the capacitor.

16. A method of programming or reading the memory cell according to claim 1, the method comprising:
applying a selection voltage to the memory cell selection element;
applying a blocking voltage to a gate of the transistor, and
applying a programming or a reading voltage to the data storage element to program or read the selected memory cell, wherein
the blocking voltage is larger than the selection voltage and lower than the programming voltage.

17. A memory device comprising the memory cell according to claim 1.

18. A memory device comprising:
a first, second, third and fourth memory cell according to claim 1, the memory cell selection element of each memory cell comprising a respective further transistor comprising a gate;
a shared data line for applying a programming or reading voltage, the shared data line being connected to the data storage element of each memory cell;
a blocking line for applying a blocking voltage, the blocking line being connected to the gate of the transistor of each memory cell;
a first and second selection line, the first selection line being connected to the further transistor of the first memory cell and to the further transistor of the third memory cell, the second selection line being connected to the further transistor of the second memory cell and to the further transistor of the fourth memory cell, and
a first and second word line, the first word line being connected to the gate of the further transistor of the first memory cell and to the gate of the further transistor of the second memory cell, the second word line being connected to the gate of the further transistor of the third memory cell and to the gate of the further transistor of the fourth memory cell, and
wherein the device is arranged such at least one of the four memory cells is selectable for programming or reading by applying a voltage to at least one of the selection and word lines.
